(19) United States
(12) Patent Application Publication
(10) Pub. No.: US 2026/0333858 A1
(43) Pub. Date: Oct. 22, 2026

(54) SEMICONDUCTOR DEVICE

(71) Applicant: Socionext Inc., Kanagawa (JP)

(72) Inventors: Atsushi OKAMOTO, Yokohama (JP); Hirotaka TAKENO, Yokohama (JP); Wenzhen WANG, Yokohama (JP)

(21) Appl. No.: 19/643,299

(22) Filed: Apr. 9, 2026

Related U.S. Application Data
(63) Continuation of application No. PCT/JP2023/037173, filed on Oct. 13, 2023.

(51) Int. Cl. H10D 84/85; H10D 30/00; H10D 30/43; H10D 62/10; H10W 20/41; H10W 20/42; H10W 20/43

(52) U.S. Cl. CPC H10D 84/851; H10D 30/43; H10D 30/502; H10D 62/121; H10W 20/427; H10W 20/43; H10W 20/435; H10W 20/42

(57) ABSTRACT

A semiconductor device includes a substrate; first, second and third power lines in the substrate; first and second semiconductor layers above the substrate; a first gate formed between the first and second semiconductor layers; and a first transistor electrically connected to the first and second power lines, and including the first and second semiconductor layers and the first gate. The semiconductor device further includes fifth and sixth semiconductor layers above the substrate; a second gate between the fifth and sixth semiconductor layers; a second transistor electrically connected to one of the first and third power lines, and including the fifth and sixth semiconductor layers and the second gate; and a third transistor electrically connected to the other of the first and third power lines, and including seventh and eighth semiconductor layers and the second gate. An output of the second transistor is electrically connected to the first gate.

### CROSS-REFERENCE TO RELATED APPLICATION

This application is a continuation application of International Application PCT/JP2023/037173 filed on Oct. 13, 2023 and designated the U.S., the entire contents of which are incorporated herein by reference.

### FIELD

The embodiments discussed herein are related to a semiconductor device.

### BACKGROUND

A CFET (Complementary Field Effect Transistor) technology in which transistors are formed in a stacked manner is known. A BPR (Buried Power Rail) technology is known in which a buried interconnect formed by forming a conductor in a trench formed in a surface of a semiconductor substrate is used to supply a power supply potential or a ground potential to a transistor. A technology is known in which a power switch circuit that controls turning on and off of supply of a power supply potential is provided in a standard cell or the like.

Patent Document 1: U.S. Patent Application Publication No. 2023/0178435

Patent Document 2: U.S. Patent Application Publication No. 2023/0067311

Patent Document 3: U.S. Patent Application Publication No. 2022/0123023

Patent Document 4: U.S. Patent Application Publication No. 2022/0181258

Patent Document 5: International Publication No. WO 2020/065916

Patent Document 6: International Publication No. WO 2020/066797

Patent Document 7: International Publication No. WO 2020/217396

Patent Document 8: International Publication No. WO 2020/217400

Patent Document 9: U.S. Patent Application Publication No. 2021/0366902

Patent Document 10: U.S. Patent Application Publication No. 2022/0102479

Patent Document 11: U.S. Patent Application Publication No. 2021/0210600

### SUMMARY

According to an aspect of an embodiment, a semiconductor device includes:
a substrate;
a first power line, a second power line, and a third power line formed in the substrate;
a first semiconductor layer and a second semiconductor layer formed above the substrate;
a third semiconductor layer formed above the first semiconductor layer;
a fourth semiconductor layer formed above the second semiconductor layer;
a first gate formed between the first semiconductor layer and the second semiconductor layer, and between the third semiconductor layer and the fourth semiconductor layer;
a first transistor electrically connected to the first power line and the second power line, the first transistor including the first semiconductor layer, the second semiconductor layer, and the first gate, or including the third semiconductor layer, the fourth semiconductor layer, and the first gate;
a fifth semiconductor layer and a sixth semiconductor layer formed above the substrate;
a seventh semiconductor layer formed above the fifth semiconductor layer;
an eighth semiconductor layer formed above the sixth semiconductor layer;
a second gate formed between the fifth semiconductor layer and the sixth semiconductor layer, and between the seventh semiconductor layer and the eighth semiconductor layer;
a second transistor electrically connected to one of the first power line and the third power line, and including the fifth semiconductor layer, the sixth semiconductor layer and the second gate; and
a third transistor electrically connected to the other of the first power line and the third power line, and including the seventh semiconductor layer, the eighth semiconductor layer and the second gate,
wherein an output of the second transistor is electrically connected to the first gate.

The object and advantages of the invention will be realized and attained by means of the elements and combinations particularly pointed out in the claims. It is to be understood that both the foregoing general description and the following detailed description are exemplary and explanatory and are not restrictive of the invention.

### BRIEF DESCRIPTION OF DRAWINGS

FIG. 1 is a plan view illustrating an example of a layout of a semiconductor device in a first embodiment;

FIG. 2 is a cross-sectional view illustrating an example of a cross-sectional structure of the semiconductor device of FIG. 1;

FIG. 3 is a circuit diagram illustrating an example of a circuit disposed in a standard cell block of FIG. 1;

FIG. 4 is a perspective view illustrating an example of a layout of the power switch circuit of FIG. 3;

FIG. 5 illustrates perspective views illustrating examples of a method of connecting a top interconnect and an interconnect of a BPR layer formed on a surface of a substrate;

FIG. 6 is a plan view illustrating an example of a plan view of the power switch circuit and the standard cell in FIG. 4, as viewed from the top interconnect side toward the substrate SUB;

FIG. 7 is a plan view illustrating an example of a plan view of the power switch circuit and the standard cell in FIG. 4, as viewed from the bottom interconnect side toward the substrate side;

FIG. 8 is a cross-sectional view illustrating an example of a cross section taken along line X1-X1′ of FIGS. 6 and 7;

FIG. 9 is a cross-sectional view illustrating an example of a cross section taken along line X2-X2′ of FIGS. 6 and 7;

FIG. 10 is a cross-sectional view illustrating an example of a cross section taken along line Y1-Y1′ of FIGS. 6 and 7;

FIG. 11 is a plan view illustrating an example of a plan view of a power switch circuit and a standard cell in a second embodiment, as viewed from the top interconnect side toward the substrate SUB; and

FIG. 12 is a plan view illustrating an example of a plan view of the power switch circuit and the standard cell in FIG. 11, as viewed from the bottom interconnect side toward the substrate side.

### DESCRIPTION OF EMBODIMENTS

In a case where a power switch circuit is formed by connecting a source or a drain of a CFET to a buried power rail (BPR) interconnect, detailed studies have not been made on layout configurations for the power switch circuit.

The present disclosure has been made in view of the above circumstances, and an objective of the present disclosure is to provide an appropriate layout for a power switch circuit formed using a CFET whose source and drain are connected to a BPR interconnect.

According to the disclosed technology, a power switch circuit formed using a CFET in which a source and a drain are connected to a BPR interconnect can be appropriately laid out.

Embodiments will be described below with reference to the drawings. In the following, reference numerals indicating signals are also used as reference numerals indicating signal lines or signal terminals. Reference numerals indicating power supply potentials are also used as reference numerals indicating power supply lines or power supply terminals to which the power supply potentials are supplied.

### First Embodiment

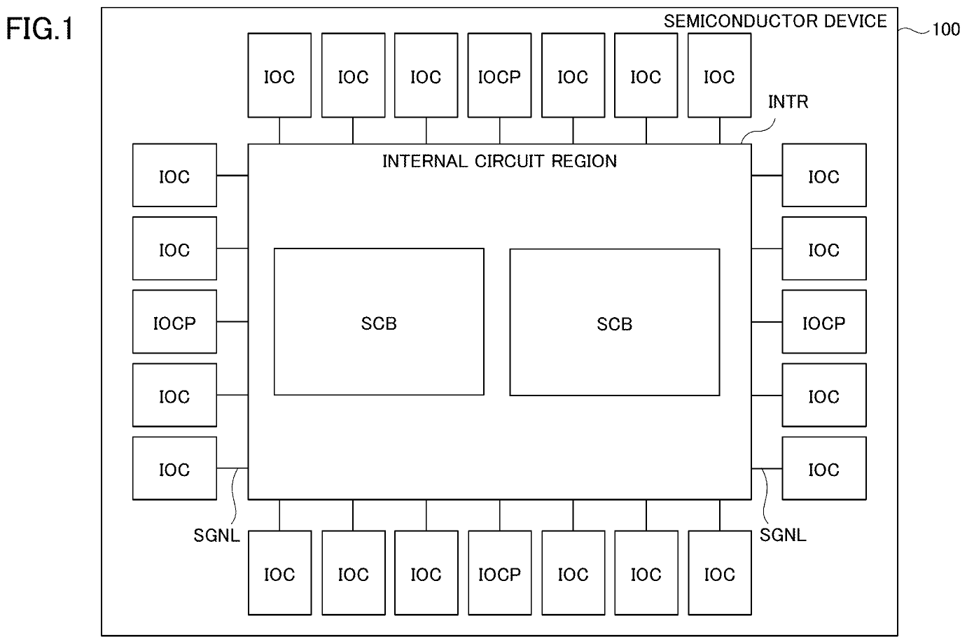

FIG. 1 illustrates an example of a layout of a semiconductor device 100 in the first embodiment. For example, the semiconductor device 100 illustrated in FIG. 1 may be an SoC (System on Chip), or may be a single FPGA (Field-Programmable Gate Array) or the like.

The semiconductor device 100 includes a plurality of I/O cells IOC and IOCP, and an internal circuit region INTR. The I/O cell IOC is an interface circuit for a signal SGNL, such as an input signal, an output signal, or an input/output signal. The I/O cell IOCP is an interface circuit for a power supply potential or a ground potential.

Each of the I/O cells IOC and IOCP is connected to the internal circuit region INTR. For example, the internal circuit region INTR includes one or more standard cell blocks SCB in which standard cells are provided. In addition, a logic circuit other than a standard cell may be provided in the internal circuit region INTR, or a memory may be provided in the internal circuit region INTR. The memory may be provided in the standard cell block SCB.

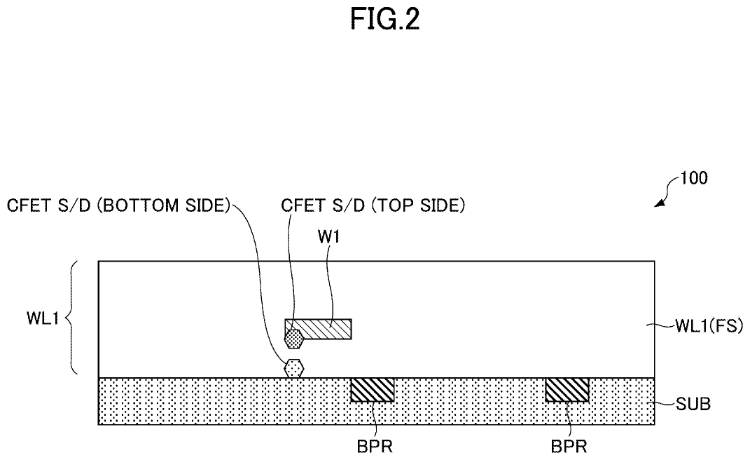

FIG. 2 illustrates an example of a cross-sectional structure of the semiconductor device 100 of FIG. 1. The semiconductor device 100 includes a substrate SUB and an interconnect layer WL1 formed on a surface FS of the substrate SUB. On the surface FS of the substrate SUB, a source/drain region S/D, which is part of a CFET, is formed on a bottom side closer to the substrate SUB, and is also formed on a top side farther from the substrate SUB. The source/drain region S/D of the CFET may be connected to an interconnect W1 formed in the interconnect layer WL1. A trench is formed on the surface FS of the substrate SUB, and a buried conductive interconnect BPR is formed in the trench.

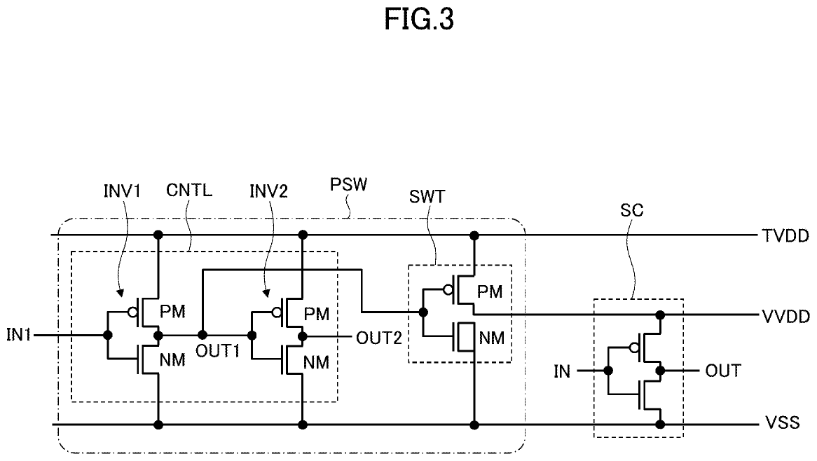

FIG. 3 illustrates an example of a circuit disposed in the standard cell block SCB of FIG. 1. The power switch circuit PSW includes a control circuit CNTL and a switch transistor SWT controlled by the control circuit CNTL.

For example, the control circuit CNTL is a buffer circuit including inverters INV1 and INV2 connected in series between an input signal line IN1 and an output signal line OUT2. Each of the inverters INV1 and INV2 operates by being connected to a power supply line TVDD and a ground line VSS. The inverter INV1 inverts the logical value of the input signal IN1 and outputs it as an output signal OUT1. The inverter INV2 inverts the logical value of the output signal OUT1 from the inverter INV1 and outputs it as an output signal OUT2.

The switch transistor SWT includes a PMOS transistor PM and an NMOS transistor NM. The PMOS transistor PM has a source connected to the power supply line TVDD and a drain connected to a virtual power supply line VVDD. The NMOS transistor NM has a source and a drain connected to the ground line VSS. The gates of the PMOS transistor PM and the NMOS transistor NM receive a control signal OUT1 output from the control circuit CNTL.

The source and the drain of the NMOS transistor NM of the switch transistor SWT may be connected to the virtual power supply line VVDD. By connecting the source and the drain of the transistor to a voltage line having a fixed potential instead of leaving them open, the potentials of the source and the drain of the transistor can be stabilized, and variations in the characteristics of the transistor can be suppressed. In addition, charge/discharge currents (leakage currents) in the source region and the drain region can be suppressed.

Further, the source and the drain of the NMOS transistor NM may be set to be floating when no problem occurs in the operation of the power switch circuit PSW. In this case, the source and the drain of the NMOS transistor NM may be interconnected by an interconnect.

FIG. 3 illustrates an example in which the standard cell SC has an inverter disposed between the virtual power supply line VVDD and the ground line VSS. The PMOS transistor included in the inverter of the standard cell SC is an example of a fourth transistor. For example, the transistors of the power switch circuit PSW and the standard cell SC are CFETs.

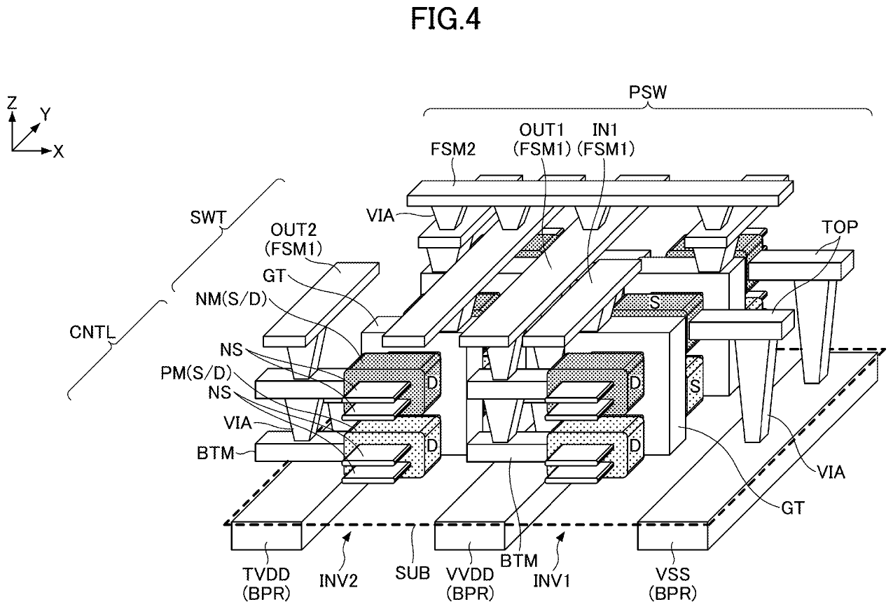

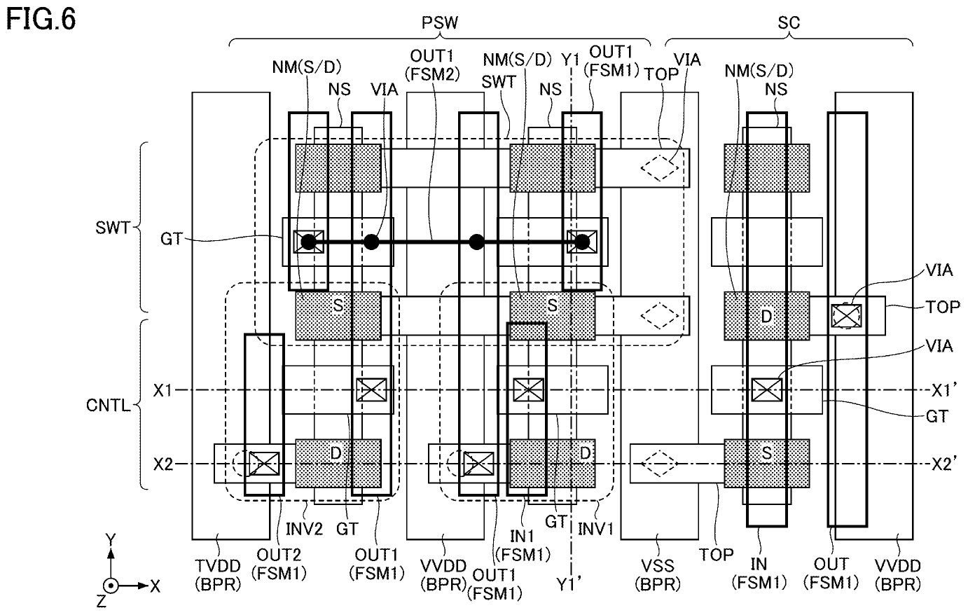

FIG. 4 illustrates an example of a layout of the power switch circuit PSW of FIG. 3. In FIG. 4, illustration of interlayer insulating films is omitted, and the substrate SUB is schematically indicated by thick broken lines. Interconnects of an interconnect layer FSM1 and an interconnect layer FSM2 will be described with reference to FIG. 6.

In the layout illustrated in FIG. 4, bottom-side semiconductor layers disposed above the substrate SUB are formed as a source/drain region S/D of a PMOS transistor PM of a CFET, and top-side semiconductor layers disposed above the bottom-side semiconductor layers are formed as a source/drain region S/D of an NMOS transistor NM of the CFET. In the CFET, two bottom-side semiconductor layers are interconnected by nanosheets NS, and two top-side semiconductor layers are interconnected by top-side nanosheets NS. In the CFET, a gate of the PMOS transistor and a gate of the NMOS transistor are common. Reference signs S and D assigned to the source/drain region S/D of the NMOS transistor NM and the PMOS transistor PM indicate a source and a drain of the transistor, respectively. The source/drain region S/D of the NMOS transistor NM has an N-type conductivity, and the source/drain region S/D of the PMOS transistor PM has a P-type conductivity. In the present disclosure, a semiconductor layer may be referred to as a source/drain region S/D even when the transistor does not function as a transistor. In addition, a part of a CFET structure may be referred to as an NMOS transistor NM or a PMOS transistor PM according to a conductivity type of the semiconductor layer, even when the transistor does not function as a transistor.

In FIG. 4, each of the PMOS transistor group and the NMOS transistor group is disposed in the order of drain, gate, source, gate, and drain along the Y direction. As illustrated in FIG. 3, the £ source and the drain of the NMOS transistor of the switch transistor SWT are connected to the ground line VSS.

In a region of the power switch circuit PSW, the control circuit CNTL is formed by source/drain regions S/D located on respective sides of a gate located on a front side in the Y direction.

Further, in the region of the power switch circuit PSW, the switch transistor SWT is formed by source/drain regions S/D located on respective sides of a gate located on a back side in the Y direction.

The PMOS transistor group and the NMOS transistor group are disposed above the substrate SUB at positions corresponding to an interval between the power supply line TVDD and the virtual power supply line VVDD of the BPR layer in plan view. That is, the PMOS transistor group and the NMOS transistor group are disposed at offset positions in the X direction in plan view with respect to the power supply line TVDD and the virtual power supply line VVDD of the BPR layer.

The inverter INV1 of the control circuit CNTL and the switch transistor SWT are formed by the PMOS transistor group and the NMOS transistor group located between the virtual power supply line VVDD and the ground line VSS in plan view. Similarly, the inverter INV2 of the control circuit CNTL and the switch transistor SWT are formed by the PMOS transistor group and the NMOS transistor group located between the power supply line TVDD and the virtual power supply line VVDD in plan view.

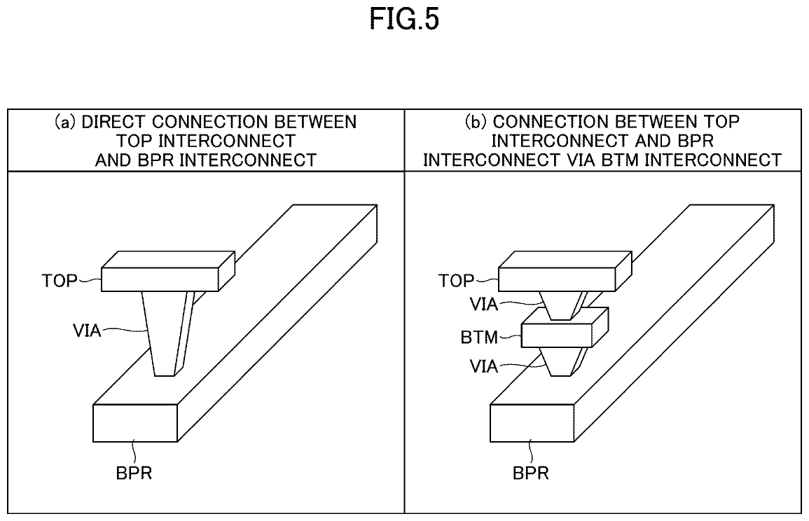

FIG. 5 illustrates examples of a connection method between a top interconnect TOP and an interconnect of a BPR layer formed in the substrate SUB. As illustrated in (a) of FIG. 5, the top interconnect TOP and the interconnect of the BPR layer may be directly connected by a via VIA without passing through a bottom interconnect BTM, similarly to the interconnect of the power switch circuit PSW in FIG. 4. As illustrated in (b) of FIG. 5, the top interconnect TOP and the interconnect of the BPR layer may be connected via a bottom interconnect BTM. Note that the interconnect method in (b) of FIG. 5 may be applied in other embodiments. The bottom interconnect BTM and the bottom-side transistor in the CFET have portions at the same position in the Z direction. Further, the top interconnect TOP and the top-side transistor in the CFET have portions at the same position in the Z direction.

FIG. 6 illustrates an example of a plan view of the power switch circuit PSW and the standard cell SC in FIG. 4 as viewed from the top interconnect TOP side toward the substrate SUB side. In FIG. 6, the source and the drain of the NMOS transistor NM to which neither of the reference signs S and D is assigned are in an open state or connected to the ground line VSS, indicating that the NMOS transistor NM does not function as a transistor.

Interconnects indicated by thick solid lines extending in the Y direction indicate interconnects of an interconnect layer FSM1 (FSM is an abbreviation for Frontside Metal) disposed on the upper side of the power switch circuit PSW and the standard cell SC (the side from the substrate SUB toward the position where the CFET is disposed in the Z direction). The interconnects of the interconnect layer FSM1 are located above the top interconnect TOP and are formed using any one of a plurality of interconnect layers on the top interconnect TOP. Hereinafter, the interconnect layer FSM1 is also referred to as an FSM1 layer.

The NMOS transistors NM of the power switch circuit PSW and the standard cell SC are disposed at offset positions in the X direction in plan view with respect to the power supply line TVDD, the virtual power supply line VVDD, and the ground line VSS of the BPR layer. The source and the drain of the NMOS transistor NM are disposed at positions corresponding to the formation region of the top interconnect TOP in the Z direction. The source and the drain of the NMOS transistor NM are disposed on respective sides in the Y direction with the gate GT interposed between the source and the drain of the NMOS transistor NM.

In the NMOS transistor NM of the switch transistor SWT, one of the source and the drain is an example of one of a third semiconductor layer and a fourth semiconductor layer, and the other of the source and the drain is an example of the other of the third semiconductor layer and the fourth semiconductor layer. The gate GT of the switch transistor SWT is an example of a first gate. In the NMOS transistors NM of the inverters INV1 and INV2 of the control circuit CNIL, one of the source and the drain is an example of one of a seventh semiconductor layer and an eighth semiconductor layer, and the other of the source and the drain is an example of the other of the seventh semiconductor layer and the eighth semiconductor layer. The gate GT of the inverters INV1 and INV2 is an example of a second gate. The NMOS transistor NM of the inverter INV1 is an example of a third transistor.

In the switch transistor SWT, the source/drain regions S/D of the NMOS transistors NM adjacent in the X direction are interconnected by the top interconnects TOP. In the switch transistor SWT, the source/drain region S/D of the NMOS transistor NM on the right side of FIG. 6 is connected to the ground line VSS of the BPR layer via the top interconnect TOP and the via VIA. As a result, the source/drain region S/D of the NMOS transistor NM of the switch transistor SWT is fixed to the ground potential VSS.

By connecting the source and the drain of the NMOS transistor NM to a voltage line having a fixed potential instead of leaving the source and the drain of the NMOS transistor NM open, the potentials of the source and the drain of the NMOS transistor NM can be stabilized, and variations in the characteristics of the NMOS transistor NM can be suppressed. In addition, charge/discharge currents (leakage currents) in the source/drain regions can be suppressed.

The gate GT of the inverter INV1 is connected to the input signal line IN1 of the FSM1 layer via a via VIA. The source S of the NMOS transistor NM of the inverter INV1 is provided in common with the source S of the NMOS transistor NM of the switch transistor SWT, and is connected to the ground line VSS via a common top interconnect TOP and a via VIA on the bottom interconnect BTM side. By sharing the source S and the top interconnect TOP, an increase in the layout size of the power switch circuit PSW can be suppressed.

The drain D of the NMOS transistor NM of the inverter INV1 is connected to the via VIA on the bottom interconnect BTM side via the top interconnect TOP, and is further connected to the output signal line OUT1 of the FSM1 layer via the upper via VIA. The output signal line OUT1 of the FSM1 layer is connected to the gate GT of the switch transistor SWT via a via indicated by a black circle, an interconnect (OUT1) of the interconnect layer FSM2, a via VIA indicated by a black circle, an interconnect (OUT1) of the FSM1 layer, and a via VIA. Further, the output signal line OUT1 of the interconnect layer FSM2 is connected to the gate of the inverter INV2 via a via VIA indicated by a black circle, an interconnect of the FSM1 layer, and a via VIA.

Hereinafter, the interconnect layer FSM2 is also referred to as an FSM2 layer. The interconnects of the interconnect layer FSM2 are located above the top interconnect TOP and are formed using any one of the interconnect layers on the top interconnect TOP other than the FSM1 layer.

The source S of the NMOS transistor NM of the inverter INV2 is provided in common with the source S of the NMOS transistor NM of the switch transistor SWT, and is connected to the source S of the adjacent NMOS transistor NM via a common top interconnect TOP. The drain D of the NMOS transistor NM of the inverter INV2 is connected to the via VIA on the bottom interconnect BTM side via the top interconnect TOP, and is further connected to the output signal line OUT2 of the FSM1 layer via the upper via VIA.

When an inverter is formed in the standard cell SC, the drain D of the NMOS transistor NM of the inverter is connected to the output signal line OUT of the interconnect layer FSM1 via the top interconnect TOP and the upper via VIA, and is connected to the bottom interconnect BTM via the top interconnect TOP and the lower via VIA. The source S of the NMOS transistor NM of the inverter is connected to the ground line VSS of the BPR layer via the top interconnect TOP and the via VIA on the bottom interconnect BTM side. The gate of the inverter is connected to the input signal line IN of the FSM1 layer via a via VIA.

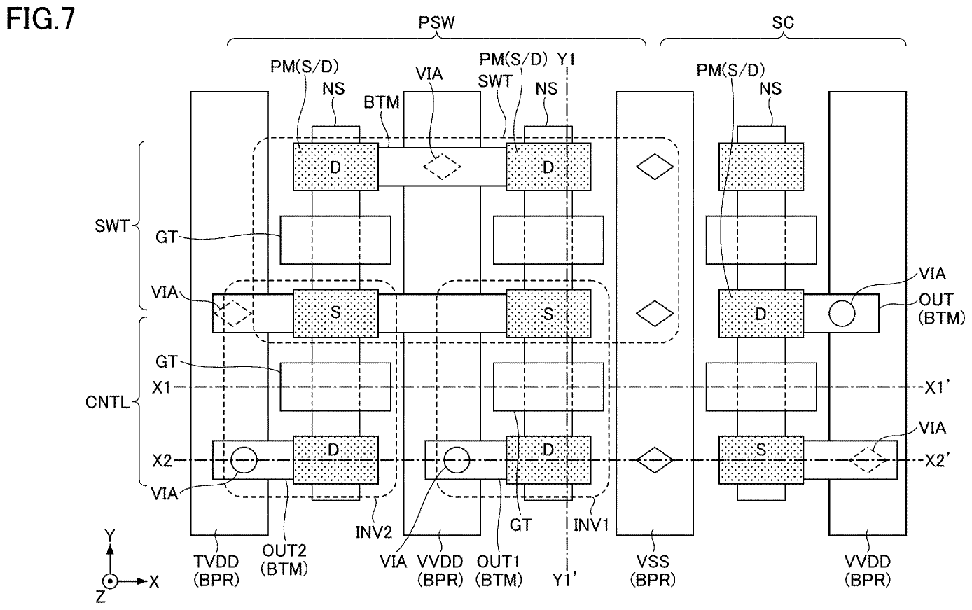

FIG. 7 illustrates an example of a plan view of the power switch circuit PSW and the standard cell SC in FIG. 4 as viewed from the bottom interconnect BTM side toward the substrate SUB side. In FIG. 7, the source and the drain of the PMOS transistor PM to which neither of the reference signs S and D is assigned are in an open state, indicating that the transistor does not function as a transistor.

The PMOS transistors PM of the power switch circuit PSW and the standard cell SC are disposed at offset positions in the X direction in plan view with respect to the power supply line TVDD, the virtual power supply line VVDD, and the ground line VSS of the BPR layer. The source and the drain of the PMOS transistor PM are disposed at positions corresponding to the formation region of the bottom interconnect BTM in the Z direction. The source and the drain of the PMOS transistor PM are disposed on respective sides in the Y direction with the gate GT interposed therebetween.

In the PMOS transistor PM of the switch transistor SWT, one of the source and the drain is an example of one of a first semiconductor layer and a second semiconductor layer, and the other of the source and the drain is an example of the other of the first semiconductor layer and the second semiconductor layer. The PMOS transistor PM of the switch transistor SWT is an example of a first transistor.

In the PMOS transistors PM of the inverters INV1 and INV2 of the control circuit CNTL, one of the source and the drain is an example of one of a fifth semiconductor layer and a sixth semiconductor layer, and the other of the source and the drain is an example of the other of the fifth semiconductor layer and the sixth semiconductor layer. The PMOS transistor PM of the inverter INV1 is an example of a second transistor.

In the switch transistor SWT, the drains D of the PMOS transistors PM adjacent in the X direction are interconnected by the bottom interconnect BTM, and are connected to the virtual power supply line VVDD of the BPR layer via the via VIA. In the switch transistor SWT and the control circuit CNTL, common sources S of the PMOS transistors PM adjacent in the X direction are interconnected via the bottom interconnect BTM. Further, in the switch transistor SWT and the control circuit CNTL, common sources S of the PMOS transistors PM located on the left side of FIG. 7 are connected to the power supply line TVDD of the BPR layer via the bottom interconnect BTM and the via VIA.

The drain D of the PMOS transistor PM of the inverter INV1 is connected to the via VIA on the top interconnect TOP side via the bottom interconnect BTM, and is connected to the output signal line OUT1 of FIG. 6. The drain D of the PMOS transistor PM of the inverter INV2 is connected to the via VIA on the top interconnect TOP side via the bottom interconnect BTM, and is connected to the output signal line OUT2 of FIG. 6.

As illustrated in FIG. 7, when the switch transistor SWT has a plurality of PMOS transistors PM, the sources S of the plurality of PMOS transistors PM may be connected to the power supply line TVDD of the BPR layer via a common bottom interconnect BTM. Further, when the virtual power supply line VVDD of the BPR layer is disposed between columns of the PMOS transistors PM formed at intervals in the X direction in plan view, the drains D of the plurality of columns of the PMOS transistors PM may be connected to the virtual power supply line VVDD of the BPR layer via a common bottom interconnect BTM. As a result, the number of bottom interconnects BTM connected to the drains D of the PMOS transistors PM can be reduced.

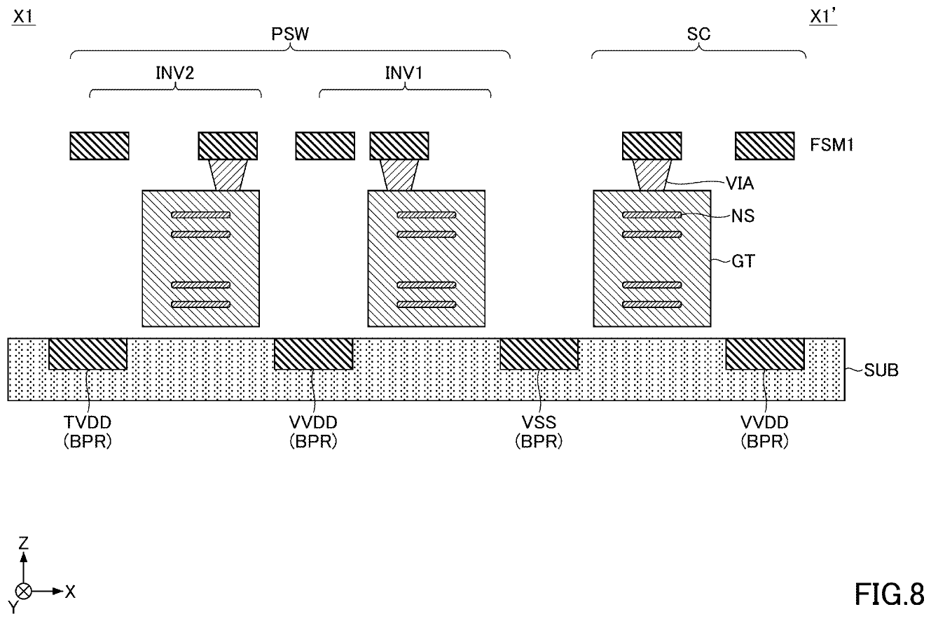

FIG. 8 illustrates an example of a cross section taken along line X1-X1′ of FIGS. 6 and 7. The gate GT of each transistor is connected to an interconnect of the FSM1 layer via a via VIA. Further, the gate GT of each transistor is disposed on the substrate SUB via an insulating film, and is disposed between interconnects of the BPR layer disposed at intervals in the X direction. The nanosheets NS are provided through the gate GT.

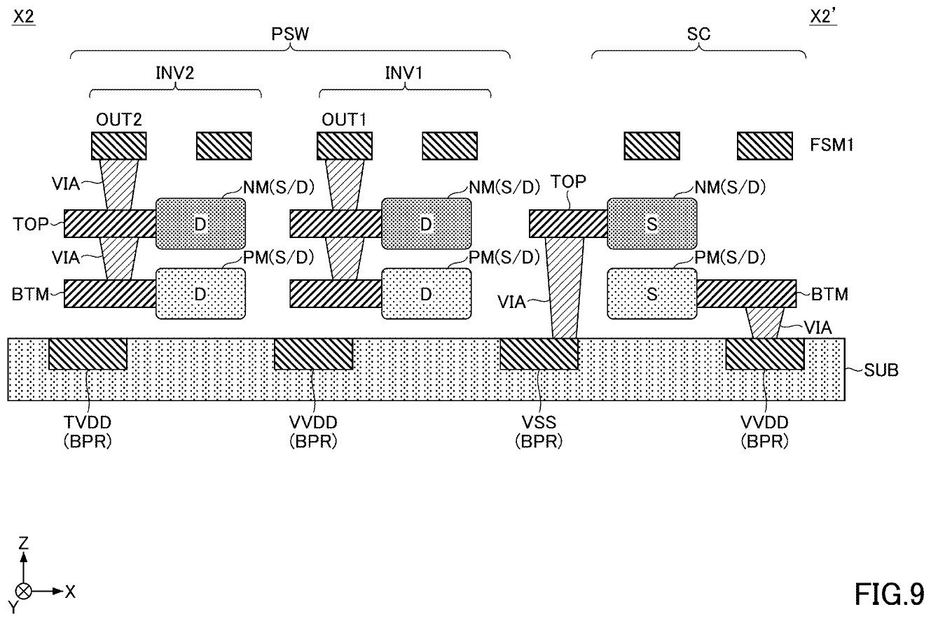

FIG. 9 illustrates an example of a cross section taken along line X2-X2′ of FIGS. 6 and 7. In the power switch circuit PSW, the drain D of each of the NMOS transistors NM of the inverters INV1 and INV2 is connected to the output signal line OUT1 or the output signal line OUT2 of the FSM1 layer via the top interconnect TOP and the via VIA. In the power switch circuit PSW, the drain D of each of the PMOS transistors PM of the inverters INV1 and INV2 is connected to the top interconnect TOP connected to the output signal line OUT1 or the output signal line OUT2 via the bottom interconnect BTM and the via VIA.

In the standard cell SC, the source S of the NMOS transistor NM is connected to the ground line VSS of the BPR layer via the top interconnect TOP and the via VIA. The source S of the PMOS transistor PM is connected to the virtual power supply line VVDD of the BPR layer via the bottom interconnect BTM and the via VIA.

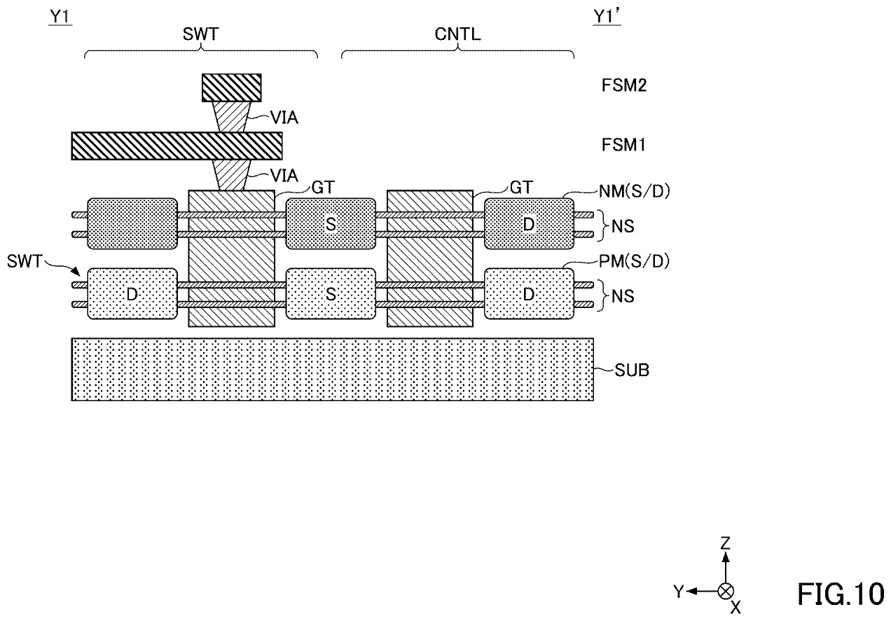

FIG. 10 illustrates an example of a cross section taken along line Y1-Y1′ of FIGS. 6 and 7. The gate GT of the switch transistor SWT is connected to an interconnect of the FSM1 layer via a via VIA, and is further connected to an interconnect of the FSM2 layer via a via VIA. Nanosheets NS are formed between the source and the drain S/D of the NMOS transistor NM and between the source and the drain S/D of the PMOS transistor PM, respectively.

As described above, in the first embodiment, by connecting the source and the drain of the CFET to the power supply line TVDD and the virtual power supply line VVDD formed in the BPR layer on the surface of the substrate SUB, the power switch circuit PSW using the CFET can be appropriately laid out. As a result, the power switch circuit PSW having a reduced circuit scale can be mounted on the semiconductor device 100.

By connecting the source and the drain of the NMOS transistor NM of the switch transistor SWT to the ground line VSS, the potentials of the source and the drain can be stabilized, and variations in the characteristics of the transistor can be suppressed. In addition, charge/discharge currents (leakage currents) in the source region and the drain region can be suppressed.

### Second Embodiment

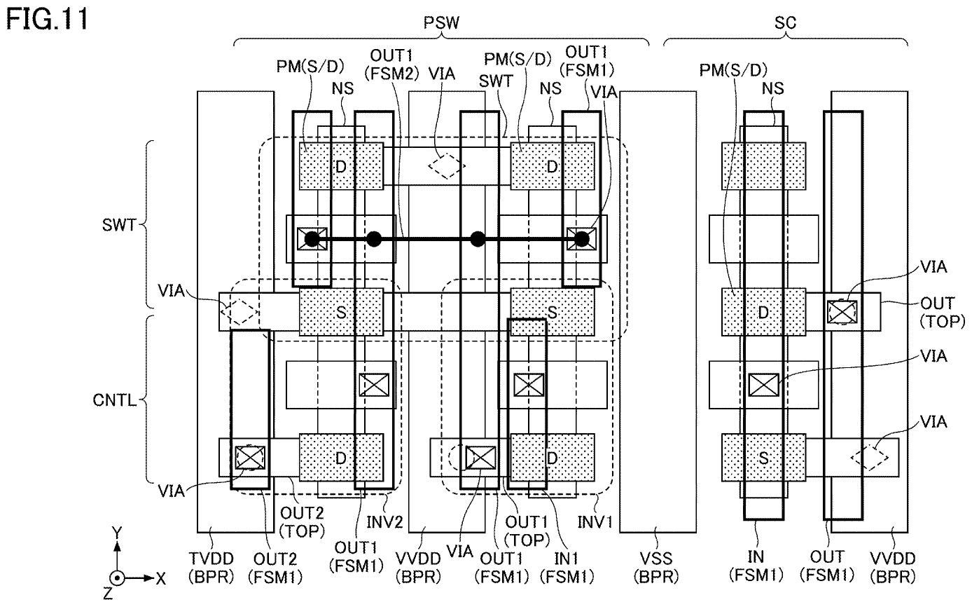

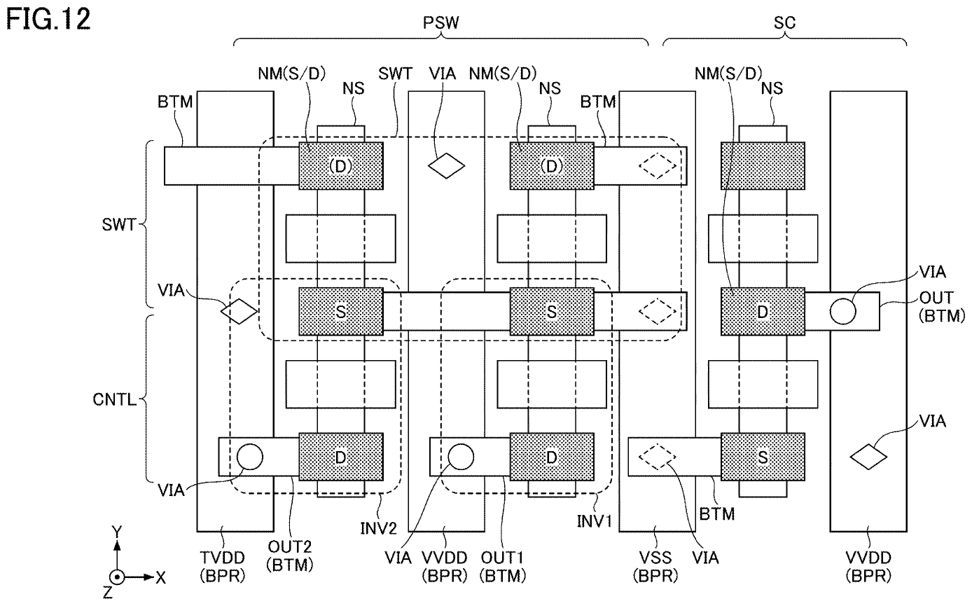

FIG. 11 illustrates an example of a plan view of a power switch circuit and a standard cell in a second embodiment, as viewed from a top interconnect side toward a substrate SUB. FIG. 12 illustrates an example of a plan view of the power switch circuit PSW and the standard cell SC in the second embodiment, as viewed from a bottom interconnect side toward a substrate side. Elements similar to those in FIGS. 4, 6, and 7 are denoted by the same reference signs, and detailed description thereof is omitted.

For example, the power switch circuit PSW and the standard cell SC illustrated in FIGS. 11 and 12 are mounted in the standard cell block SCB of the semiconductor device 100 as in FIG. 1. The cross-sectional structure of the semiconductor device 100 in which the power switch circuit PSW and the standard cell SC of FIGS. 11 and 12 are mounted is the same as that of FIG. 2. Examples of circuits of the power switch circuit PSW and the standard cell SC illustrated in FIGS. 11 and 12 are the same as those in FIG. 3.

FIGS. 11 and 12 are different from the layout of FIG. 4 in that the positions of the PMOS transistor PM and the NMOS transistor NM in the Z direction in each CFET are reversed from those in FIG. 4. That is, in FIGS. 11 and 12, the source/drain region S/D of the PMOS transistor PM is disposed on the top side, and the source/drain region S/D of the NMOS transistor NM is disposed on the bottom side.

In FIG. 11, the drain D of the PMOS transistor PM of the switch transistor SWT is connected to the virtual power supply line VVDD of the BPR layer via the top interconnect TOP and the via VIA. A common source S of the PMOS transistor PM of the switch transistor SWT and the PMOS transistors PM of the inverters INV1 and INV2 is connected to the power supply line TVDD of the BPR layer via the top interconnect TOP and the via VIA.

The drains D of the PMOS transistors PM of the inverters INV1 and INV2 are connected to bottom-side vias VIA via top interconnects TOP (output signal line OUT1 or output signal line OUT2), respectively, and are further connected to upper-side vias VIA. The gate GT of the inverter INV1 is connected to the input signal line IN1 via a via VIA. The gate GT of the inverter INV2 and the gate GT of the switch transistor SWT are connected to the output signal line OUT1 via a via VIA.

In the standard cell SC, the source S of the PMOS transistor PM is connected to the virtual power supply line VVDD of the BPR layer via the top interconnect TOP and the via VIA. In the standard cell SC, the drain D of the PMOS transistor PM is connected to the bottom-side via VIA via the top interconnect TOP, and is further connected to the upper-side via VIA.

In FIG. 12, a common source S of the NMOS transistor NM of the switch transistor SWT and the NMOS transistors NM of the inverters INV1 and INV2 is connected to the ground line VSS of the BPR layer via the top interconnect TOP and the via VIA.

The drain D of the NMOS transistor NM of the switch transistor SWT is connected to the ground line VSS of the BPR layer via the bottom interconnect BTM and the via VIA. Note that, in the switch transistor SWT, the bottom interconnect BTM connected to the drain D of the NMOS transistor NM located on the left side of FIG. 12 is connected to the ground line VSS of the BPR layer via a via VIA in a region not illustrated.

The drains D of the NMOS transistors NM of the inverters INV1 and INV2 are connected to the top interconnects of FIG. 11 via bottom interconnects BTM (output signal line OUT1 or output signal line OUT2) and vias VIA, respectively.

In the standard cell SC, the drain D of the NMOS transistor NM is connected to the top interconnect TOP of FIG. 11 via the bottom interconnect BTM and the via VIA. In the standard cell SC, the source S of the NMOS transistor NM is connected to the ground line VSS of the BPR layer via the bottom interconnect BTM and the via VIA.

As described above, in the second embodiment, as in the first embodiment, by connecting the source and the drain of the CFET to the power supply line TVDD and the virtual power supply line VVDD formed in the BPR layer on the surface of the substrate SUB, the power switch circuit PSW using the CFET can be appropriately laid out. As a result, the power switch circuit PSW having a reduced circuit scale can be mounted on the semiconductor device 100.

By connecting the source and the drain of the NMOS transistor NM of the switch transistor SWT to the ground line VSS, the potentials of the source and the drain can be stabilized, and variations in the characteristics of the transistor can be suppressed. In addition, charge/discharge currents (leakage currents) in the source region and the drain region can be suppressed.

In the first embodiment and the second embodiment described above, examples of layouts are illustrated in which a circuit such as an inverter of the standard cell SC is connected to the virtual power supply line VVDD and the ground line VSS, and the power switch circuit PSW generates the virtual power supply potential VVDD. However, in another example, the present disclosure may be applied to a layout in which a circuit such as an inverter of the standard cell SC is connected to the power supply line VDD and a virtual ground line VVSS, and the power switch circuit PSW generates the virtual ground potential VVSS.

In this case, the switch transistor SWT of the power switch circuit PSW may have an NMOS transistor NM connecting the ground line VSS to the virtual ground line VVSS, and a PMOS transistor PM whose source and drain are connected to the power supply line VDD or the virtual ground line VVSS. The source and the drain of the PMOS transistor PM of the switch circuit PSW may be set to an open state. Further, the switch transistor SWT may be formed of only the NMOS transistor NM, and the PMOS transistor PM may not be formed.

Although the present disclosure has been described based on the respective embodiments, the disclosure is not limited to the requirements illustrated in the embodiments. Various modifications may be made without departing from the scope of the disclosure, and components may be appropriately determined according to the application forms thereof.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a illustrating of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A semiconductor device comprising:
a substrate;
a first power line, a second power line, and a third power line formed in the substrate;
a first semiconductor layer and a second semiconductor layer formed above the substrate;
a third semiconductor layer formed above the first semiconductor layer;
a fourth semiconductor layer formed above the second semiconductor layer;
a first gate formed between the first semiconductor layer and the second semiconductor layer, and between the third semiconductor layer and the fourth semiconductor layer;
a first transistor formed electrically connected to the first power line and the second power line, the first transistor including the first semiconductor layer, the second semiconductor layer, and the first gate, or including the third semiconductor layer, the fourth semiconductor layer, and the first gate;
a fifth semiconductor layer and a sixth semiconductor layer formed above the substrate;
a seventh semiconductor layer formed above the fifth semiconductor layer;
an eighth semiconductor layer formed above the sixth semiconductor layer;
a second gate formed between the fifth semiconductor layer and the sixth semiconductor layer, and between the seventh semiconductor layer and the eighth semiconductor layer;
a second transistor electrically connected to one of the first power line and the third power line, and including the fifth semiconductor layer, the sixth semiconductor layer and the second gate; and
a third transistor electrically connected to the other of the first power line and the third power line, and including the seventh semiconductor layer, the eighth semiconductor layer and the second gate,
wherein an output of the second transistor is electrically connected to the first gate.

2. The semiconductor device according to claim 1,
wherein the first transistor includes the first semiconductor layer, the second semiconductor layer, and the first gate, and
wherein the third semiconductor layer and the fourth semiconductor layer are electrically interconnected.

3. The semiconductor device according to claim 1,
wherein the first semiconductor layer and the second semiconductor layer have a conductivity type different from a conductivity type of the third semiconductor layer and the fourth semiconductor layer.

4. The semiconductor device according to claim 3, further comprising a plurality of the first transistors, wherein the third semiconductor layer and the fourth semiconductor layer of each of the plurality of the first transistors are electrically interconnected.

5. The semiconductor device according to claim 1,
wherein the third semiconductor layer and the fourth semiconductor layer are electrically connected to the third power line.

6. The semiconductor device according to claim 1, further comprising:
an interconnect connected to either the first semiconductor layer or the second semiconductor layer of the first transistor; and
a standard cell electrically connected to the second power line and the third power line and including a fourth transistor,
wherein the interconnect is connected to a source of the fourth transistor.

7. The semiconductor device according to claim 1,
wherein one of the fifth semiconductor layer or the sixth semiconductor layer is integrally formed with the first semiconductor layer, and
wherein one of the seventh semiconductor layer or the eighth semiconductor layer is integrally formed with the third semiconductor layer.
